(19) United States
(12) Patent Application Publication
(10) Pub. No.: US 2002/0014351 A1
(43) Pub. Date: Feb. 7, 2002

(54) Module-mounting motherboard device

(75) Inventors: Masanobu Okada, Sagamihara-shi (JP); Kazuyoshi Nakaya, Yokohama-shi (JP)

Correspondence Address: OSTROLENK FABER GERB & SOFFEN, 1180 AVENUE OF THE AMERICAS, NEW YORK, NY, 100368403

(73) Assignee: Murata Manufacturing Co., Ltd.

(21) Appl. No.: 09/870,893

(22) Filed: May 31, 2001

(30) Foreign Application Priority Data
Jun. 1, 2000 (JP) 2000-164379

(51) Int. Cl. H05K 7/20

(52) U.S. Cl. 174/252; 174/260; 361/720

(57) ABSTRACT

A motherboard is provided with a through-hole in a region thereof on which a module is mounted in contact with the motherboard. Heat, generated when heating the motherboard and the module so as to connect with each other by soldering, can quickly dissipate, in a cooling process, through the through-hole from a substrate of the module in which the heat is likely to accumulate, whereby unevenness of temperature distribution through the module can be suppressed. By virtue of the through-hole provided in the region of the motherboard in which the heat is likely to accumulate, the heat can also quickly dissipate from the region of the motherboard, whereby the unevenness of temperature distribution through the motherboard can be alleviated. The module and the motherboard are prevented from warping due to the unevenness of temperature distribution, whereby unstable connection is avoided.

### BACKGROUND OF THE INVENTION

1. Field of the Invention

The present invention relates to a motherboard for mounting a module.

2. Description of the Related Art

FIG. 4 is a schematic-sectional view of a module. A module 1 shown in FIG. 4 includes a ceramic substrate 2, and a case 3 connected to the substrate 2 at the upper surface thereof. A circuit 5 is formed on the substrate 2 in a region thereof which is covered by the case 3, including circuit components 4, conductive patterns (not shown), and the like. The substrate 2 is provided with electrode parts (not shown) at marginal ends (portions not covered by the case 3) of the substrate 2, which are electrically connected to the circuit 5 disposed in the case 3.

The module 1 is mounted on a motherboard 8 via, for example, solder parts 7, as shown in FIG. 5A. Only the substrate 2 among a plurality of components forming the module 1 is shown in FIG. 5A, and the case 3, the circuit components 4, and the like are omitted. FIG. 5 also shows connecting electrodes 10 formed on the motherboard 8. The connecting electrodes 10 formed at positions to which the solder parts 7 are connected serve to improve joining property between the motherboard 8 and the solder parts 7. The solder parts 7 are connected to the electrode parts of the module 1. The circuit 5 of the module 1 can be electrically connected to another circuit disposed at the motherboard 8 side via the solder parts 7.

When mounting the module 1 on the motherboard 8, the solder parts 7 are formed in predetermined soldering positions on the substrate 2 of the module 1, as shown in FIG. 5A, the substrate 2 of the module 1 is positioned on the motherboard 8 as designed, and is placed on the motherboard 8.

Then, the motherboard 8 with the module 1 placed thereon is heated in a reflow furnace, whereby the solder parts 7 are melted and adheres to the connecting electrodes 10 of the motherboard 8, thereby bonding the module 1 to the motherboard 8 via solder parts 7. In this case, the substrate 2 of the module 1 and the motherboard 8 are coherent to each other at the bottom face of the substrate 2 and a surface of the motherboard 8 as mounting faces.

After heating, the motherboard 8 solder-mounted with the module 1 is cooled. Thus, the module 1 is mounted on the motherboard 8 via the solder parts 7.

However, a problem has been found in the conventional module-mounting motherboard having the above-described configuration in that the module 1 cannot be reliably mounted on the motherboard 8 via the solder parts 7. That is, the substrate 2 of the module 1 is adhered to the surface of the motherboard 8 at the overall mounting face of the substrate 2 when the motherboard 8 with the module 1 placed thereon is heated in the reflow furnace and the solder parts 7 are melted. Therefore, in the cooling process after heating, a central part of the substrate 2 and a central part of a region S for mounting the module 1 in which the module is in contact with the region S (hereinafter referred to as a module-mounting-and-contacting region S) are not easily cooled because heat is accumulated at the central parts of the substrate 2 and the module-mounting-and-contacting region S, while the marginal ends of the substrate 2 of the module 1 and the periphery of the module-mounting-and-contacting region S are quickly cooled. The temperature of the substrate 2 and in the module-mounting-and-contacting region S increases toward the central part of the module-mounting-and-contacting region S from the periphery thereof, that is, the temperature is unevenly distributed.

Due to the unevenly distributed temperature, the substrate 2 and the motherboard 8 warp so as to separate away from each other, as shown in FIG. 5B, whereby the connection between the substrate 2 and the motherboard 8 via the solder parts 7 is made unstable.

### SUMMARY OF THE INVENTION

Accordingly, it is an object of the present invention to provide a module-mounting motherboard device including a motherboard on which a module can be reliably mounted.

To the end, according to an aspect of the present invention, a module-mounting motherboard device comprises a motherboard having at least one through-hole formed in a region of the motherboard on which a module is mounted in contact with the motherboard. The through-hole serves to enhance heat dissipation from the module to suppress warp of the motherboard attributable to insufficient heat dissipation, thereby preserving a sufficient area of contact between the module and the motherboard.

The through-hole may be disposed at least in a central portion of the region of the motherboard on which the module is mounted in contact with the motherboard.

Since the motherboard according to the present invention is provided with at least one through-hole in the region of the motherboard on which the module is mounted in contact with the motherboard, for example in a cooling process after heating for soldering the module to the motherboard, heat can quickly dissipate directly through the through-hole from a part of the module which is in contact with the motherboard, in which the heat is likely to accumulate, whereby the part of the module can be quickly cooled and unevenness of heat distribution through the module can be significantly alleviated, thereby substantially avoiding warp of the module due to the unevenness of heat distribution.

The motherboard is provided with the through-hole in the region on which the module is mounted in contact with the motherboard, that is, in a region in which heat is likely to accumulate. Therefore, the heat does not accumulate in the region of the motherboard and unevenness of heat distribution through the motherboard can be significantly alleviated, thereby substantially avoiding the warp of the motherboard.

The module and the motherboard can be substantially prevented from warping, as described above, whereby the unstable connection between the module and the motherboard due to the warp thereof can be substantially avoided.

The conventional motherboard described above is not provided with a through-hole; therefore, the motherboard is likely to significantly warp, and the motherboard and the module come into point contact, whereby the contact area between the motherboard and the module becomes very small, and the connection therebetween becomes unstable. According to the present invention, on the other hand, the warp of the motherboard can be avoided by the through-hole, the motherboard and the module are in plane contact, and the contact area between the motherboard and the module can be increased compared with the conventional motherboard. Moreover, even when the motherboard warps, the warp of the motherboard can be suppressed to small extent by the through-hole. When the through-hole is disposed, for example, substantially at a central part of the region of the motherboard on which the module is mounted in contact with the motherboard, the module comes into plane contact with the motherboard at the edge of the through-hole of the motherboard. Therefore, the contact area between the motherboard and the module is made greater compared with the conventional motherboard, whereby the module is mounted on the motherboard in contact therewith unstable manner.

### BRIEF DESCRIPTION OF THE DRAWINGS

FIG. 1 is an illustration of a module-mounting motherboard according to an embodiment of the present invention;

FIGS. 2A, 2B, and 2C are illustrations of module-mounting motherboards according to respective other embodiments of the present invention;

FIGS. 3A and 3B are illustrations of the module-mounting motherboard, showing advantages obtained according to the embodiments of the present invention;

FIG. 4 is a sectional view of a module; and

FIGS. 5A and 5B are illustrations of a conventional module-mounting motherboard.

### DESCRIPTION OF THE PREFERRED EMBODIMENTS

Embodiments according to the present invention are described below with reference to the drawings.

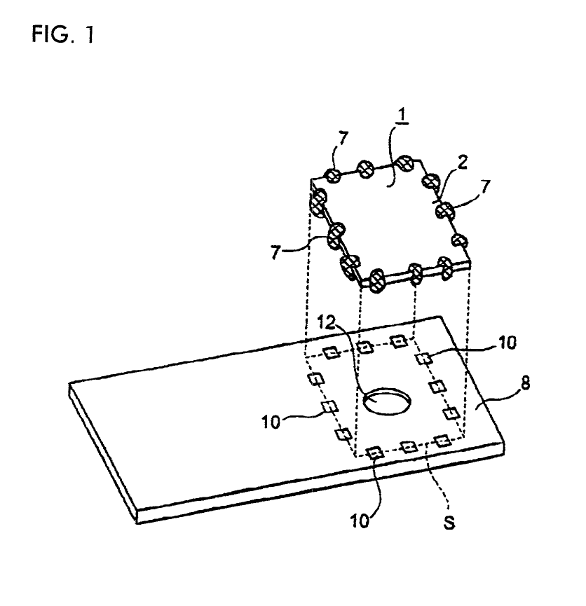

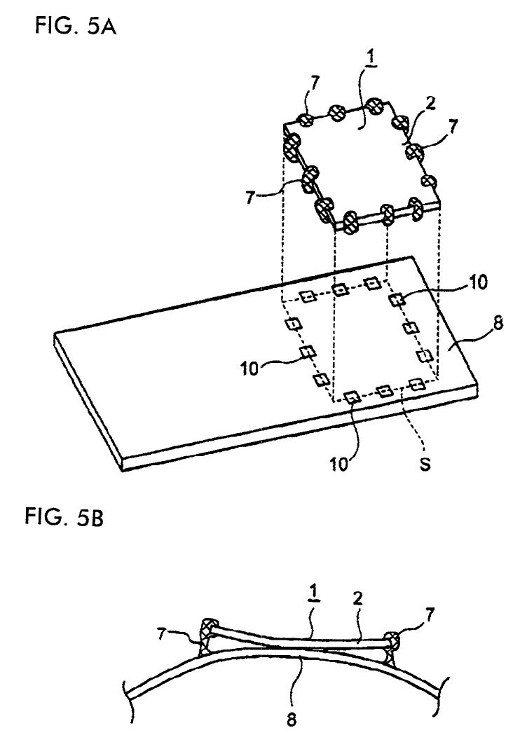

FIG. 1 is a schematic view of a module-mounting motherboard according to an embodiment of the present invention and a substrate which is a component of the module. The same components as those which are used in the conventional module-mounting motherboard described above are referred to with the same reference numerals as those used in FIGS. 5A and 5B, for which description is not repeated.

In FIG. 1, a motherboard 8 is provided with a through-hole 12 in a region S of the motherboard 8 for mounting a module 1 in a manner such that the module 1 is in contact with the motherboard 8 at the region S thereof (hereinafter referred to as a module-mounting-and-contacting region S).

The through-hole 12 is positioned at a central part of the module-mounting-and-contacting region S of the motherboard 8. By providing the through-hole 12 in the motherboard 8, heat directly dissipates to the outside, in a cooling process after heated in a reflow furnace for solder-mounting the module 1 on the motherboard 8, through the through-hole 12 from the central part of a substrate 2 of the module 1 from which the heat does not quickly dissipate otherwise, thereby accelerating cooling. Therefore, the substrate 2 can be cooled at the same speed at the central part of the substrate 2 as at the periphery thereof. The substrate 2 can be cooled substantially at the same temperature-decrease-rate through the overall region of the substrate 2.

Since the module-mounting-and-contacting region S, which is a portion of the motherboard 8 from which the heat does not easily dissipate, is cut away at the central part thereof, the heat can quickly dissipate from the central part of the module-mounting-and-contacting region S, whereby the module-mounting-and-contacting region S can be cooled at the same speed of cooling through the overall region S, and the module-mounting-and-contacting region S can be cooled while the temperature thereof is distributed substantially evenly through the overall region S.

The substrate 2 and the motherboard 8 can be substantially prevented from warping caused by unevenly distributed temperature because the temperature can be distributed evenly through the substrate 2 and the motherboard 8 in the cooling process, as described above. Therefore, unreliable soldering caused by the warped substrate 2 and the motherboard 8 can be avoided.

Particularly, when a large module is mounted on the motherboard 8, heat does not quickly dissipate from a large contact part between the module 1 and the motherboard 8, whereby uneven temperature-distribution is likely to occur when cooling. This problem can be avoided by providing the above through-hole 12.

According to the present embodiment, the size of the through-hole 12 is set by performing experiments and computation by considering the thickness and materials of the substrate 2 and the motherboard 8, the area of the module-mounting-and-contacting region S, and the like so that the uneven temperature distribution through the module 1 and the substrate 8 can be avoided and the warp of the substrate 2 and the motherboard 8 can be minimized in the cooling process.

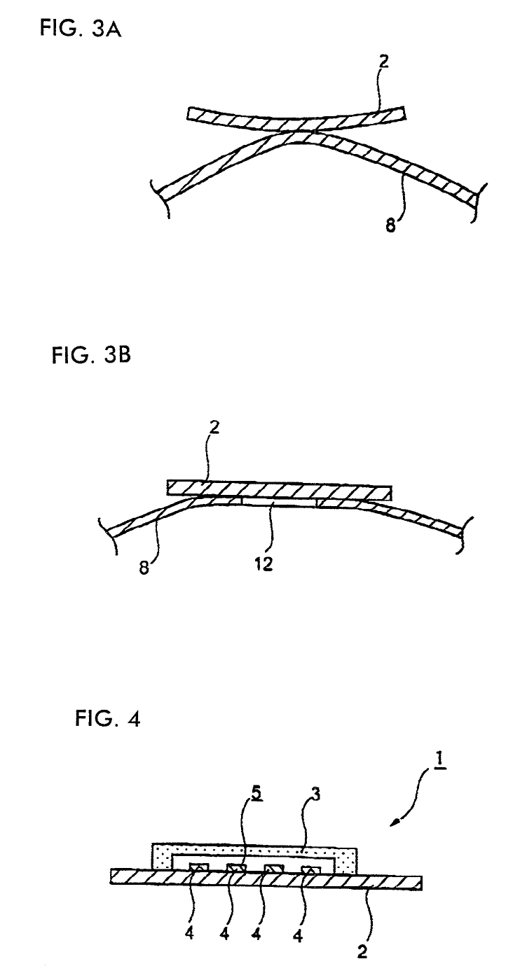

Even when the periphery of the module-mounting-and-contacting region S and the marginal ends of the substrate 2 are separated away from each other due to the warp of the motherboard 8 in spite of providing the through-hole 12, the gap between the periphery of the module-mounting-and-contacting region S and the marginal ends of the substrate 2 can be minimized. This is because the motherboard 8 bends at the edge of the through-hole 12 which is formed according to the present embodiment, as shown in FIG. 3B, while the motherboard 8 bends at the central part of the module-mounting-and-contacting region S when the through-hole 12 is not formed, as shown in FIG. 3A, whereby the distance to the periphery of the module-mounting-and-contacting region S from the point at which the motherboard 8 bends decreases according to the present embodiment. Moreover, the warp of the motherboard 8 can be reduced, even when it warps, because the unevenness of the temperature in the motherboard 8 is avoided by the through-hole 12.

As described above, when the periphery of the module-mounting-and-contacting region S of the warped motherboard 8 and the marginal ends of the substrate 2 are separated away from each other in spite of the through-hole 12, the gap between the periphery of the module-mounting-and-contacting region S and the marginal ends of the substrate 2 can be small so as to maintain a reliable soldered state, whereby the module 1 and the motherboard 8 which are reliably soldered to each other are obtainable.

When the through-hole 12 is not provided, as in a case of the conventional motherboard, the substrate 2 of the module 1 and the motherboard 8 are brought into point contact with each other when the motherboard 8 warps, as shown in FIG. 3A, whereby the area of contact between the substrate 2 and the motherboard 8 significantly decreases. Therefore, the mounted state of the module 1 on the motherboard 8 becomes unstable.

On the other hand, by providing the through-hole 12, according to the present embodiment, the warp of the motherboard 8 can be minimized even when it warps, as shown in FIG. 3B, and the substrate 2 and the motherboard 8 are brought into plane contact at the edge of the through-hole 12. Therefore, the area of contact between the substrate 2 and the motherboard 8 is made greater compared with the case in which the through-hole 12 is not provided, whereby the mounted state of the module 1 on the motherboard 8 becomes stable.

According to the above-described embodiment, the motherboard 8 for reliably mounting the module 1 is obtainable by providing the through-hole 12 in the module-mounting-and-contacting region S of the motherboard 8.

Heat-dissipation property of the module 1 can be improved because the heat generated when driving the module 1 can be directly dissipated to the outside from the bottom of the module 1 through the through-hole 12.

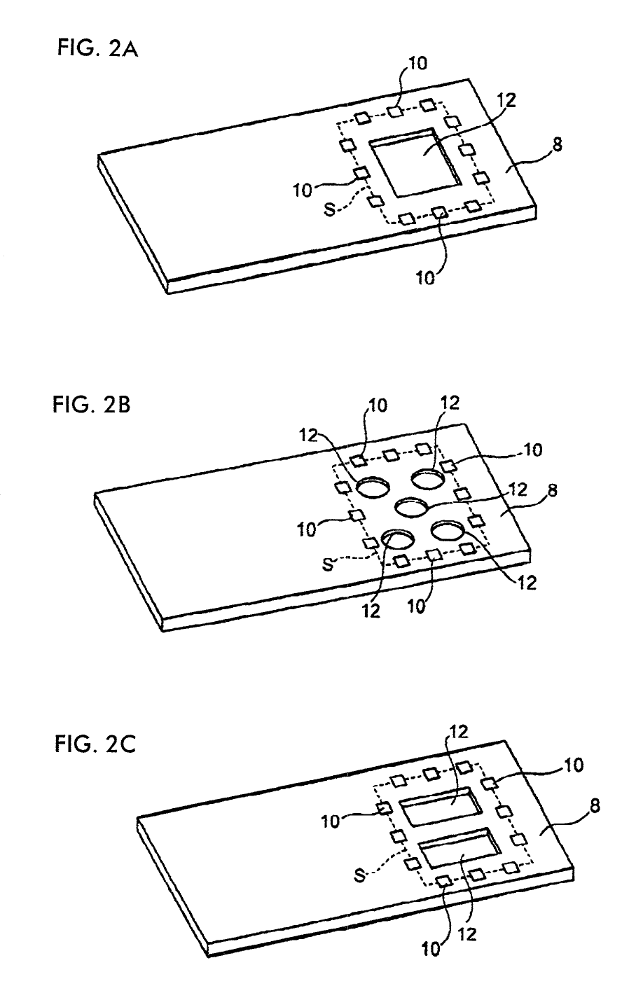

The present invention is not limited to the above-described embodiment, and it is intended to cover other various embodiments. For example, although according to the above embodiment, the though-hole 12 is circular, the through-hole 12 may be square, as shown in FIG. 2A, be polygonal such as triangular or pentagonal, or be elliptic. The through-hole 12 may be formed in any size as long as the substrate 2 and the motherboard 8 can be prevented from warping caused by the unevenness of temperature-distribution. For example, the through-hole 12 may have a larger size in which the overall module-mounting-and-contacting region S is cut away except for a peripheral portion required for soldering.

Although according to the above embodiment, the single through-hole 12 is provided, a plurality of the through-holes 12 may be provided, as shown in FIG. 2B. The plurality of through-holes 12 may have the same size as each other or sizes differing from each other. The plurality of through-holes 12 may be disposed in any positions as long as the substrate 2 and the motherboard 8 can be prevented from warping.

Although according to the above embodiment, the through-hole 12 is positioned in the central part of the module-mounting-and-contacting region S of the motherboard 8, a plurality of the through-holes 12 may be positioned in portions other than the central part of the module-mounting-and-contacting region S, as shown in FIG. 2C. The through-hole 12 may be disposed in any position in the module-mounting-and-contacting region S as long as the unevenness of temperature distribution can be reduced.

The configuration of the module 1 mounted on the motherboard 8 according to the present invention is not limited to that which is described in the above embodiment, and it may be formed in other ways.

What is claimed is:

1. A module-mounting motherboard device comprising:
a motherboard having at least one through-hole formed in a region of the motherboard on which a module is mounted in contact with the motherboard, said through-hole serving to enhance heat dissipation from the module to suppress warp of the motherboard attributable to insufficient heat dissipation, thereby preserving a sufficient area of contact between the module and the motherboard.

2. A module-mounting motherboard device according to claim 1, wherein said through-hole is disposed at least in a central portion of the region of the motherboard on which the module is mounted in contact with the motherboard.
